(19) United States
(12) Patent Application Publication
(10) Pub. No.: US 2026/0031164 A1
(43) Pub. Date: Jan. 29, 2026

(54) CORRECTIVE PROGRAM CONVERGENCE ASSOCIATED WITH MEMORY CELLS OF A MEMORY SUB-SYSTEM

(71) Applicant: MICRON TECHNOLOGY, INC., Boise, ID (US)

(72) Inventors: Yu-Chung Lien, San Jose, CA (US); Hanping Chen, San Jose, CA (US); Murong Lang, San Jose, CA (US); Zhenming Zhou, San Jose, CA (US)

(21) Appl. No.: 18/785,479

(22) Filed: Jul. 26, 2024

(51) Int. Cl. G11C 16/34; G11C 16/12

(52) U.S. Cl. CPC G11C 16/3459; G11C 16/12; G11C 16/3404

(57) ABSTRACT

A memory device including a memory array including a memory cell connected to a target wordline; and a first wordline adjacent to the target wordline, wherein the first wordline is to be programmed immediately subsequent to the target wordline; and control logic, operatively coupled with the memory array, to perform operations including causing a first programming pulse to be applied to the target wordline associated with the memory cell; causing a program verify operation to be performed on the memory cell to verify programming of the memory cell to a target programming level; determining that a measured threshold voltage of the memory cell satisfies a threshold criterion; identifying a fixed bitline bias level associated with the memory cell; identifying, based on programming level information of the first wordline, a bitline voltage offset associated with the memory cell; and causing, during applying a second programming pulse, an adjusted analog bitline voltage to be applied to the memory cell, wherein the adjusted analog bitline voltage is based on the fixed bitline bias level adjusted by the bitline voltage offset.

### TECHNICAL FIELD

Embodiments of the disclosure relate generally to memory sub-systems, and more specifically, relate to corrective program convergence associated with memory cells of a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1A illustrates an example computing system that includes a memory sub-system, in accordance with one or more embodiments of the present disclosure.

FIG. 1B is a block diagram of a memory device in communication with a memory sub-system controller of a memory sub-system, in accordance with one or more embodiments of the present disclosure.

FIG. 2A-2B are schematics of portions of an array of memory cells as could be used in a memory of the type described with reference to FIG. 1B, in accordance with one or more embodiments of the present disclosure.

FIG. 3 is a flow diagram of an example method of implementing corrective program convergence associated with memory cells of a memory sub-system, in accordance with one or more embodiments of the present disclosure.

FIG. 4 illustrates an example graph including a representation of corrective program convergence associated with memory cells, in accordance with one or more embodiments of the present disclosure.

FIG. 5 illustrates an example graph including a representation of applying adjusted bitline voltage to selected memory cells to implement corrective program convergence associated with the memory cells, in accordance with one or more embodiments of the present disclosure.

FIG. 6 is a flow diagram of an example method 500 to implement corrective program convergence associated with memory cells of a memory sub-system, in accordance with one or more embodiments of the present disclosure.

FIGS. 7A and 7B illustrate example data structures that store bitline voltage offsets in accordance with one or more embodiments of the present disclosure.

FIG. 8 is a block diagram of an example computer system in which implementations of the present disclosure can operate.

### DETAILED DESCRIPTION

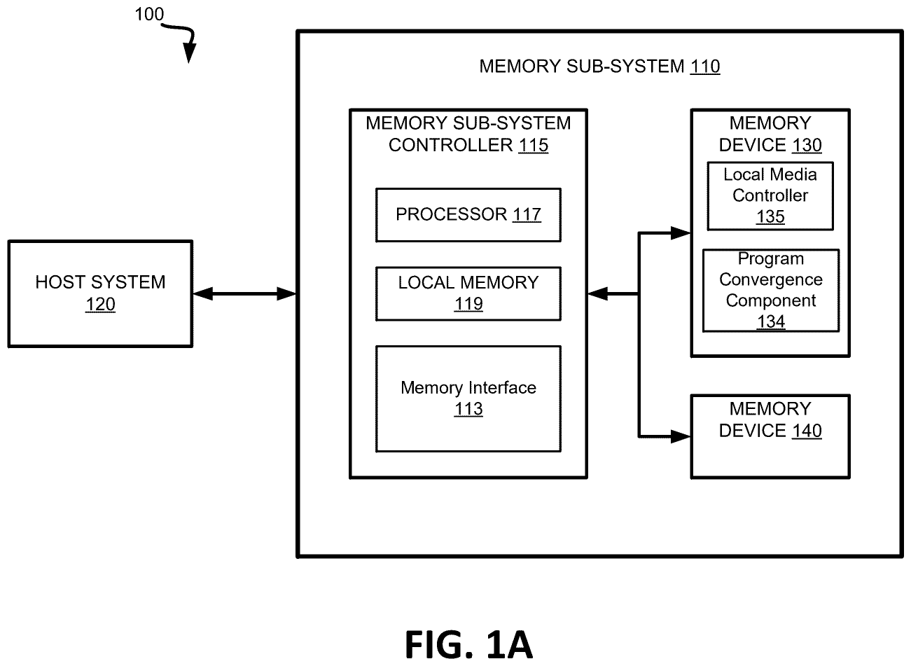

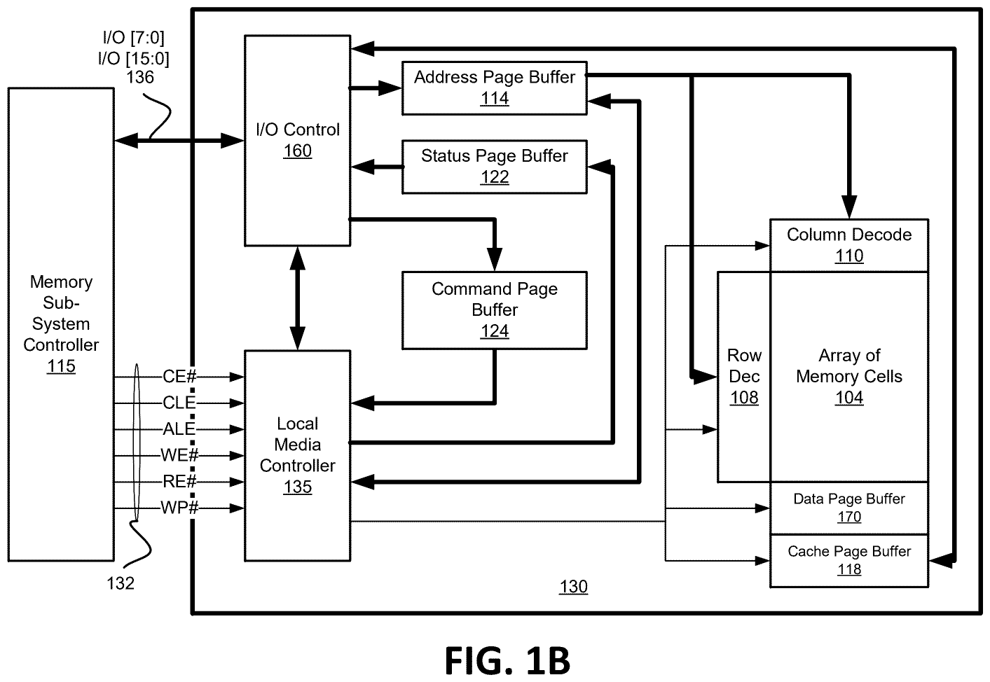

Aspects of the present disclosure are directed to corrective program convergence associated with memory cells of a memory sub-system. A memory sub-system can be a storage device, a memory module, or a hybrid of a storage device and memory module. Examples of storage devices and memory modules are described below in conjunction with FIGS. 1A-1B. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a negative-and (NAND) memory device. Other examples of non-volatile memory devices are described below in conjunction with FIGS. 1A-1B. A non-volatile memory device is a package of one or more memory dies. Each die can consist of one or more planes. For some types of non-volatile memory devices (e.g., NAND devices), each plane consists of a set of physical blocks. Each block consists of a set of pages. Each page consists of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can include multiple memory cells arranged in a two-dimensional or three-dimensional grid. The memory cells are formed onto a silicon wafer in an array of columns (also hereinafter referred to as bitlines) and rows (also hereinafter referred to as wordlines). A wordline can refer to one or more conductive lines of a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form a plane of the memory device in order to allow concurrent operations to take place on each plane. The memory device can include circuitry that performs concurrent memory page accesses of two or more memory planes. For example, the memory device can include a respective access line driver circuit and power circuit for each plane of the memory device to facilitate concurrent access of pages of two or more memory planes, including different page types. For ease of description, these circuits can be generally referred to as independent plane driver circuits. Control logic on the memory device includes a number of separate processing threads to perform concurrent memory access operations (e.g., read operations, program operations, and erase operations). For example, each processing thread corresponds to a respective one of the memory planes and utilizes the associated independent plane driver circuits to perform the memory access operations on the respective memory plane. As these processing threads operate independently, the power usage and requirements associated with each processing thread also varies.

Some memory devices can be three-dimensional (3D) memory devices (e.g., 3D NAND devices). For example, a 3D memory device can include memory cells that are placed between sets of layers including a pillar (e.g., polysilicon pillar), a tunnel oxide layer, a charge trap (CT) layer, and a dielectric (e.g., oxide) layer. A 3D memory device can have a “top deck” corresponding to a first side and a “bottom deck” corresponding to a second side. Without loss of generality, the first side can be a drain-side and the second side can be a source-side. For example, a 3D memory device can be a 3D replacement gate memory device having a replacement gate structure using wordline stacking.

A memory cell (“cell”) can be programmed (written to) by applying a certain voltage to the cell, which results in an electric charge being held by the cell. For example, a voltage signal V_{CG} that can be applied to a control electrode of the cell to open the cell to the flow of electric current across the cell, between a source electrode and a drain electrode. More specifically, for each individual cell (having a charge Q stored thereon) there can be a threshold control gate voltage V_{T}(also referred to as the “threshold voltage”) such that the source-drain electric current is low for the control gate voltage (V_{CG}) being below the threshold voltage, V_{CG}<V_{T}. The current increases substantially once the control gate voltage has exceeded the threshold voltage, V_{CG}>V_{T}. Because the actual geometry of the electrodes and gates varies from cell to cell, the threshold voltages can be different even for cells implemented on the same die. The cells can, therefore, be characterized by a distribution P of the threshold voltages, P(Q,V_{T})=dW/dV_{T}, where dW represents the probability that any given cell has its threshold voltage within the interval [V_{T}, V_{T}+dV_{T}] when charge Q is placed on the cell.

A memory device can exhibit threshold voltage distributions P(Q,V_{T}) that are narrow compared with the working range of control voltages tolerated by the cells of the device. Accordingly, multiple non-overlapping distributions P(Qₖ, V_{T}) (“valleys”) can be fit into the working range allowing for storage and reliable detection of multiple values of the charge Qₖ, k=1, 2, 3 . . . The distributions (valleys) are interspersed with voltage intervals (“valley margins”) where none (or very few) of the cells of the device have their threshold voltages. Such valley margins can, therefore, be used to separate various charge states Qₖ-the logical state of the cell can be determined by detecting, during a read operation, between which two valley margins the respective threshold voltage V_{T}of the cell resides. Specifically, the read operation can be performed by comparing the measured threshold voltage V_{T}exhibited by the memory cell to one or more reference voltage levels corresponding to known valley margins (e.g., centers of the margins) of the memory device.

One type of cell is a single level cell (SLC), which stores 1 bit per cell and defines 2 logical states (“states”) (“1” or “LO” and “0” or “L1”) each corresponding to a respective V_{T}level. For example, the “1” state can be an erased state and the “0” state can be a programmed state (L1). Another type of cell is a multi-level cell (MLC), which stores 2 bits per cell and defines 4 states (“11” or “L0”, “10” or “L1”, “01” or “L2” and “00” or “L3”) each corresponding to a respective V_{T}level. For example, the “11” state can be an erased state and the “01”, “10” and “00” states can each be a respective programmed state. Another type of cell is a triple level cell (TLC), which stores 3 bits per cell and defines 8 states (“111” or “L0”,“110” or “L1”, “101” or “L2”, “100” or “L3”, “011” or “L4”, “010” or “L5”, “001” or “L6”,and “000” or “L7”) each corresponding to a respective V_{T}level. For example, the “111” state can be an erased state and each of the other states can be a respective programmed state. Another type of a cell is a quad-level cell (QLC), which stores 4 bits per cell and defines 16 states L0-L15, where L0 corresponds to “1111” and L15 corresponds to “0000”. Another type of cell is a penta-level cell (PLC), which stores 5 bits per cell and defines 32 states. Other types of cells are also contemplated. A memory device can include one or more arrays of memory cells such as SLCs, MLCs, TLCs, QLCs, PLCs, etc. or any combination of such. For example, a memory device can include an SLC portion, and an MLC portion, a TLC portion, a QLC portion, or a PLC portion of cells.

A valley margin can also be referred to as a read window. For example, in a SLC cell, there is 1 read window that exists with respect to the 2 V distributions. As another example, in an MLC cell, there are 3 read windows that exist with respect to the 4 V_{T} distributions. As yet another example, in a TLC cell, there are 7 read windows that exist with respect to the 8 V_{T} distributions. As yet another example, in a QLC cell, there are 16 read windows that exist with respect to the 16 V_{T} distributions. Read window size generally decreases as the number of states increases. For example, the 1 read window for the SLC cell may be larger than each of the 3 read windows for the MLC cell, and each of the 3 read windows for the MLC cell may be larger than each of the 7 read windows for the TLC cell, etc. Read window budget (RWB) refers to the cumulative value of the read windows.

Memory access operations (e.g., a program operation, an erase operation, etc.) can be executed with respect to the memory cells by applying a wordline bias voltage to wordlines to which memory cells of a selected page are connected. For example, during a programming operation, one or more selected memory cell can be programmed with the application of a programming voltage to a selected wordline. In one approach, an incremental step pulse programming (ISPP) process or scheme can be employed to maintain a tight cell threshold voltage distribution for higher data reliability. In ISPP, a series of pulses of voltage levels having an increasing magnitude (e.g., by a predefined pulse step height) are applied to wordlines to which one or more memory cells are connected to gradually raise the voltage level of the memory cells to above a wordline voltage level corresponding to the memory access operation (e.g., a target program level). The application of the uniformly increasing pulses by a wordline driver of the memory device enables the selected wordline to be ramped or increased to a wordline voltage level (V_{w1}) corresponding to a memory access operation. Similarly, a series of voltage pulses having a uniformly increasing voltage level can be applied to the wordline to ramp the wordline to the corresponding wordline voltage level during the execution of an erase operation.

The series of incrementing voltage programming pulses are applied to the selected wordline to increase a charge level, and thereby a threshold voltage, of each memory cell connected to that wordline. After each programming pulse, or after a number of programming pulses, a program verify operation is performed to determine if the threshold voltage of the one or more memory cells has increased to a desired programming level. For example, the pulses can be incrementally increased in value (e.g., by a step voltage value such as 0.33V) to increase a charge stored on a charge storage structure corresponding to each pulse. The memory device can reach a target programming level voltage for a particular programming level by incrementally storing or increasing amounts of charge corresponding to the programming step voltage.

As a memory device ages, the Vt distributions tend to be widened and therefore a higher program pulse may be required toward the end of life of a memory device to ensure data can be read properly. In some cases, to tighten the Vt distributions, one approach involves the use of selective slow program convergence (SSPC). In SSPC, a program operation is performed by applying incrementally increased programming pulses to the wordline, and after each programming pulse, a program verify operation is performed to verify whether the memory cell is programmed to a target programming level. When it is determined that the memory cell has not been programmed to a target programming level, the memory controller determines whether the threshold voltage of the memory cell reaches a pre-verify threshold voltage value (V_{pre-verify}) for the target programming level. Only when the threshold voltage of the memory cell reaches V_{pre-verify} for the target programming level, the bitline connected to that memory cell is biased from a ground voltage level (e.g., 0V) to a fixed voltage level during the subsequent programming pulse to slow down the change in Vₜ. The other memory cells that do not have threshold voltage reaching V_{pre-verify} continue to be programmed at their normal pace. The memory controller may continue with the subsequent programming pulse, which is increased by a step voltage from the previous programming pulse. Since the voltage drop across the memory cell transistor is now reduced due to the bitline voltage increase, the increased programming pulse will have a reduced effect on programming speed of the memory cell. The program operation continues until the memory cell is programmed to the target programming level and the bitline voltage is increased to the inhibit voltage (e.g., Vcc). According to this approach, each bitline that is coupled to a memory cell of the plurality of memory cells is selectively biased with a bitline voltage in response to the threshold voltage of the associated memory cell reaching a pre-verify threshold voltage level. The biased bitline voltage is in a fixed value that is typically greater than ground level (i.e., 0V) and less than the inhibit voltage (e.g., V_{CC}) and is applied uniformly.

An improved approach is analog selective slow program convergence (aSSPC), which, instead of using a uniform bitline voltage, uses an analog or continuous voltage applied to the bitline (“analog bitline voltage level” or “continuous bitline voltage level”). That is, instead of biasing the bitline voltage suddenly to a fixed value at the time of threshold voltage of the associated memory cell reaching a pre-verify threshold voltage, the bitline voltage is biased continuously starting from the time that threshold voltage of the associated memory cell reaching a pre-verify threshold voltage until the bitline voltage reaches the fixed value at the time of threshold voltage of the associated memory cell reaching a program verify threshold voltage. However, additional improvement of narrowing the threshold voltage distribution width is still needed, such as for the situation of cell-to-cell interference or severe lateral charge migration. For example, cell-to-cell interference (also referred to as “C2C interference”) may exist in a memory array between the target cells and their respective groups of adjacent cells. Cell-to-cell interference can lead to Vt distribution shift. Cell-to-cell interference, in addition to intrinsic charge loss, can further lead to a widening of V_{T} distributions. The V_{T} distribution widening can cause RWB degradation, which can negatively affect memory device reliability. For example, RWB degradation can lead to an increase in the number of errors (e.g., bit errors) and/or error rate (e.g., bit error rate (BER)). Cell-to-cell interference can result in the loss of RWB in view of the Vt difference between cells on a target wordline (WLn) and neighboring wordlines, mostly the subsequent neighbor wordline (WLn+1). Specifically, cell-to-cell interference can cause the threshold voltage of the target wordline to shift up, with a larger shift occurring as the threshold voltage of WLn+1 increases.

Aspects of the present disclosure address the above and other deficiencies by implement a new program convergence that further tunes the bitline voltage of a memory cell connected to the target wordline (WLn) used in aSSPC by using the programming level information of immediately subsequent neighbor wordline (WLn+1). Specifically, after applying a first programming pulse, a program convergence component in the memory device may perform a program verify operation by applying a voltage to the target wordline (WLn) to verify the programming level (e.g., whether the measured threshold voltage has reached the a program verify threshold voltage level (Vₚᵥ) of the target programming level). Upon determining that the programming level has not been reached (i.e., the measured threshold voltage has not reached the a program verify threshold voltage level (Vₚᵥ) of the target programming level), the program convergence component may compare the measured threshold voltage with a pre-verify threshold voltage value (V_{pre-verify}). Upon determining that the measured threshold voltage is larger than the pre-verify threshold voltage value (V_{pre-verify}), the program convergence component may identify a fixed bitline bias level (Vsspc) associated with the memory cell, where the fixed bitline bias level (Vsspc) can be determined via a look-up operation of a stored or predetermined value. The fixed bitline bias level (Vsspc) may be a preset value that is greater than ground voltage level (i.e., 0V) and less than the inhibit voltage (e.g., V_{CC}).

In some implementations, a bitline voltage offset may be specifically determined such that the bitline voltage applied to the target memory cells and adjusted by the bitline voltage offset can compensate for cell-to-cell (C2C) coupling with achieving a desired RWB increase. For example, the bitline voltage offset may be determined based on the programming level information of immediately subsequent neighbor wordline (WLn+1). The bitline voltage offset is specific to the programming level of the target memory cell connected to the target wordline (WLn). For easy illustration, a target memory cell connected to a target wordline (WLn) can be referred to as a victim memory cell, while a memory cell can be referred to as an aggressor memory cell if the memory cell is connected to immediately subsequent neighbor wordline (WLn+1) and the programming level of the memory cell affects a threshold voltage of the victim memory cell. The programming level information of immediately subsequent neighbor wordline (WLn+1) may depend on the number of bits of information reflecting a threshold voltage of one or more aggressor memory cells of the immediately subsequent neighbor wordline (WLn+1) and be categorized as described below.

In an illustrative example, the target memory cell may be a TLC type of cell, which can be programmed to programming levels L0-L7. For each programming level, a respective bitline voltage offset is determined based on the programming level of aggressor memory cell. For example, in a situation where programming level information of 1-bit aggressor memory cell is used, the programming levels of the aggressor memory cell can be categorized as high or low programming level (e.g., C1, C2) since those two categorizations can be represented with a single binary bit. In this example, the program component can determine that the effects of the aggressor memory cell programmed to the low programming level C1 may not need to be compensated and can use the default bitline voltage to program the target memory cell (or may need to use a bitline voltage offset (e.g., Xn mV) less than the default bitline voltage); and the program component can determine that the bitline voltage used to compensate for the effect of the target memory cells caused by the aggressor memory cells programmed to the high programming level C2 may need a bitline voltage offset (e.g., Yn mV) less than the default bitline voltage used regardless of the programming level to which the target memory cell is being programmed. Using the above example, for programming level L1 of the target memory cell, when the aggressor memory cell is to be programmed to the low programming level C1, bitline voltage offset X1 is used, and when the aggressor memory cell is to be programmed to the high programming level C2, bitline voltage offset Y1 is used; for programming level L2 of the target memory cell, when the aggressor memory cell is to be programmed to the low programming level C1, bitline voltage offset X2 is used, and when the aggressor memory cell is to be programmed to the high programming level C2, bitline voltage offset Y2 is used; and so on. As such, for each programming level of the target memory cell, for each categorized programming level (e.g., based on the 1-bit programming level (e.g., low programming level C1 or high programming level C2)) of the aggressor memory cell, a respective bitline voltage offset is used. Similarly, for each programming level of the target memory cell, in a situation where programming level information of 2-bit aggressor memory cell is used, the programming levels of the aggressor memory cell can be categorized to either be four categorized programming level (e.g., C1, C2, C3, C4), for each categorized programming level of the aggressor memory cell, a respective bitline voltage offset is used.

In an embodiment, the bitline voltage offset may be determined via a look-up of a stored or predetermined value corresponding to a programming level of the target wordline (WLn) and a categorized programming level of the immediately subsequent neighbor wordline (WLn+1).

In an embodiment, instead of providing respective bitline voltage offset to each programming level of the target memory cell, certain programming levels of the target memory cell can be grouped such that they can use the same bitline voltage offsets. For example, the program component can initially group the programming levels of the target memory cell into one group, which means that regardless of the programming level to which the target memory cell is being programmed, the same bitline voltage offsets are used. In some implementations, having grouped the programming levels into one group, the program component can cycle through a pre-determined set of potential bitline voltage offset values until the value that maximizes the RWB increase is found. Further, the value that results in the greatest RWB increase for the grouping can be compared to the maximum RWB increase (i.e., the RWB increase resulting from perfect compensation e.g., as calculated by using the Law of Total Variance, to determine the reduction of the spread of the Vt distribution for a particular programming level) to determine whether the target RWB increase is achieved. If the greatest RWB increase that can be obtained using the chosen grouping of the specified cell programming levels is not equal to or greater than the target RWB increase, the program component can divide the programming levels into more groups.

Continuing using illustrative example described above, the program component can group the programming levels of the target memory cell into two groups. For example, programming levels L0-L3 can be grouped as a first group and programming levels L4-L7 can be grouped as a second group. For example, in a situation where programming level information of 1-bit aggressor memory cell is used, for each programming level in the first group (i.e., L0-L3), when the aggressor memory cell is to be programmed to the low programming level C1, bitline voltage offset X3 is used, and when the aggressor memory cell is to be programmed to the high programming level C2, bitline voltage offset Y3 is used. For each programming level in the second group (i.e., L4-L7), when the aggressor memory cell is to be programmed to the low programming level C1, bitline voltage offset X4 is used, and when the aggressor memory cell is to be programmed to the high programming level C2, bitline voltage offset Y4 is used.

Upon identifying the fixed bitline bias level (Vsspc) and the bitline voltage offset, the program convergence component may cause, during applying a second programming pulse, an adjusted analog bitline voltage to be applied to the memory cell, where the adjusted analog bitline voltage is a continues voltage starting from the ground voltage level (e.g., 0V) until reaching the adjusted bitline bias level, where the adjusted bitline bias level is the fixed bitline bias level reduced by the bitline voltage offset. As such, the programming speed of the second programming pulse is slowed down, and the resulted Vt distribution is tightened.

This new program convergence scheme can be used in various logical wordline sequence writing, including source to drain or drain to source. This new program convergence scheme can be used with various cell types, including MLC, TLC, QLC, PLC, etc. This new program convergence scheme can be used by system normal block usage, partial good block usage or potential block-by-deck (BBD) usage. This new program convergence scheme may be used for other types of vertical non-volatile memory device, including resistive random-access memory (ReRAM), phase-change random-access memory (PCRAM), etc.

Advantages of the present disclosure also include tightening Vt distribution, including mitigating the effects of C2C coupling and lateral charge migration by applying the adjusted analog bitline voltage based on the threshold voltage of the memory cell. Other memory cells being programmed are unaffected by the bitline biasing of the target memory cell and are allowed to be programmed at their normal programming speed. This results in an improved narrowing the threshold voltage distribution to maintain a target distribution width and faster programming times without reducing the programming throughput. Also, latency associated with program operation is reduced and performance of the memory device is improved.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IOT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Pillar, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a negative-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level memory cells (SLC) can store one bit per memory cell. Other types of memory cells, such as multi-level memory cells (MLCs), triple level memory cells (TLCs), quad-level memory cells (QLCs), and penta-level memory cells (PLCs) can store multiple bits per memory cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory page buffers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local controller) on the die and a controller (e.g., memory sub-system controller 115) for media management within the same memory device package. An example of a managed memory device is a managed NAND (MNAND) device.

In one embodiment, the memory sub-system 110 includes a memory interface component 113. Memory interface component 113 is responsible for handling interactions of memory sub-system controller 115 with the memory devices of memory sub-system 110, such as memory device 130. For example, memory interface component 113 can send memory access commands corresponding to requests received from host system 120 to memory device 130, such as program commands, read commands, or other commands. In addition, memory interface component 113 can receive data from memory device 130, such as data retrieved in response to a read command or a confirmation that a program command was successfully performed. For example, the memory sub-system controller 115 can include a processor 117 (processing device) configured to execute instructions stored in local memory 119 for performing the operations described herein.

In one embodiment, memory device 130 includes a program convergence component 134 configured to carry out corresponding memory access operations, in response to receiving the memory access commands from memory interface 113 and implement the corrective programming convergence associated with memory cells of memory device 130. In some embodiments, local media controller 135 includes at least a portion of program convergence component 134 and is configured to perform the functionality described herein. In some embodiments, program convergence component 134 is implemented on memory device 130 using firmware, hardware components, or a combination of the above. In some embodiments, the memory sub-system controller 115 includes at least a portion of the program convergence component 134. For example, the controller 115 can include a processor 117 (processing device) configured to execute instructions stored in local memory 119 for performing the operations described herein. In one embodiment, program verify component 134 receives, from a requestor, such as memory interface 113, a request to program data to a memory array of memory device 130. The memory array can include an array of memory cells formed at the intersections of wordlines and bitlines. In one embodiment, the memory cells are grouped in to blocks, which can be further divided into sub-blocks, where a given wordline is shared across a number of sub-blocks, for example. In one embodiment, each sub-block corresponds to a separate plane in the memory array. The group of memory cells associated with a wordline within a sub-block is referred to as a physical page. In one embodiment, there can be multiple portions of the memory array, such as a first portion where the sub-blocks are configured as SLC memory and a second portion where the sub-blocks are configured as multi-level cell (MLC) memory (i.e., including memory cells that can store two or more bits of information per cell). For example, the second portion of the memory array can be configured as TLC memory. The voltage levels of the memory cells in TLC memory form a set of 8 programming distributions representing the 8 different combinations of the three bits stored in each memory cell. Depending on how they are configured, cach physical page in one of the sub-blocks can include multiple page types. For example, a physical page formed from single level cells (SLCs) has a single page type referred to as a lower logical page (LP). Multi-level cell (MLC) physical page types can include LPs and upper logical pages (UPs), TLC physical page types are LPs, UPs, and extra logical pages (XPs), and QLC physical page types are LPs, UPs, XPs and top logical pages (TPs). For example, a physical page formed from memory cells of the QLC memory type can have a total of four logical pages, where each logical page can store data distinct from the data stored in the other logical pages associated with that physical page. In one embodiment, program verify component 134 can receive data to be programmed to the memory device 130 (e.g., a TLC memory device). Accordingly, program convergence component 134 can execute a program operation to program cach memory cell to one of 8 possible programming levels (i.e., voltages representing the 8 different values of those three bits).

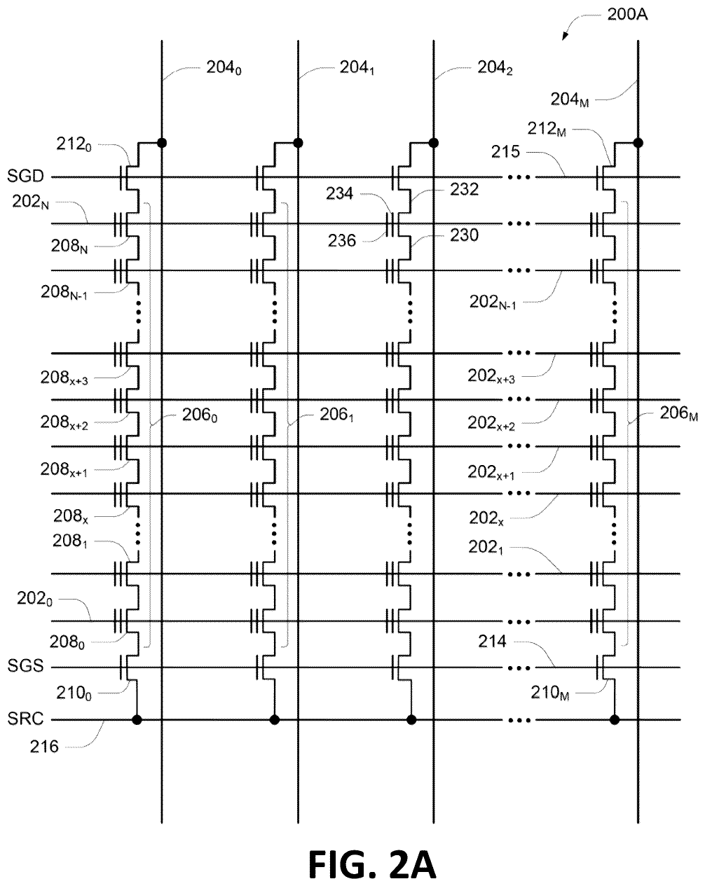

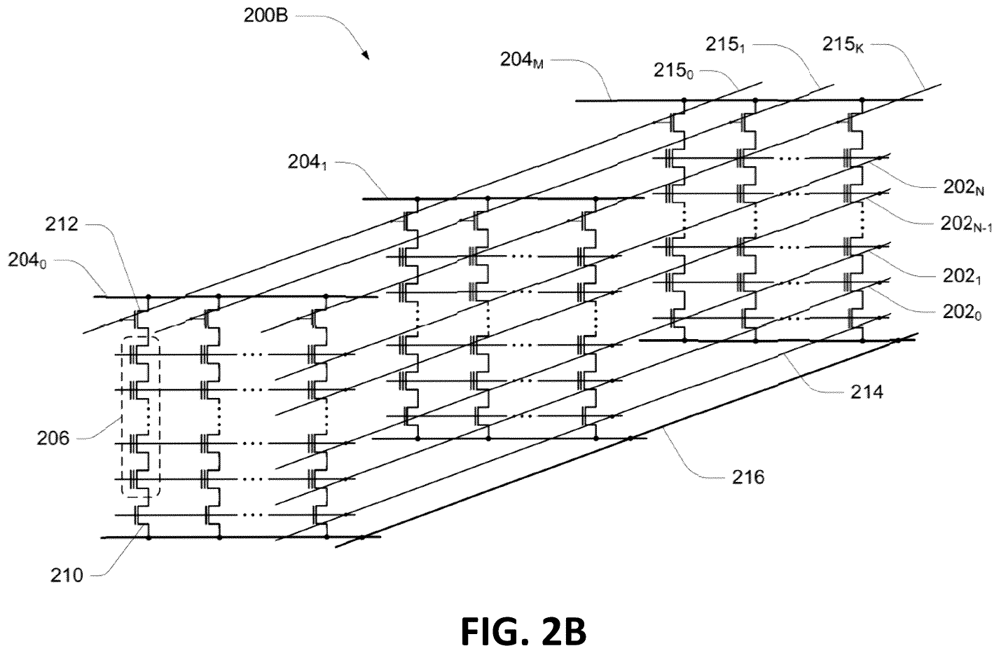

In one embodiment, the program convergence component 134 can reduce a program threshold voltage distribution width of a Vt distribution by slowing program convergence associated with selected memory cells of a memory sub-system. The program convergence component 134 manages the convergence by causing a bitline of one or more selected memory cells to be biased with an analog or continuous voltage level and an additional bitline voltage offset to establish a bitline voltage applied to a target wordline (WLn), thereby slowing of the movement of the threshold voltage for the one or more selected memory cells. Further details with regards to the operations of the program convergence component 134 will be described in further detail below with reference to FIGS. 2A-8.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device.

Memory device 130 includes an array of memory cells 104 logically arranged in rows and columns. Memory cells of a logical row are connected to the same access line (e.g., a wordline) while memory cells of a logical column are selectively connected to the same data line (e.g., a bitline). A single access line may be associated with more than one logical row of memory cells and a single data line may be associated with more than one logical column. Memory cells (not shown in FIG. 1B) of at least a portion of array of memory cells 104 are capable of being programmed to one of at least two target data states.

Row decode circuitry 108 and column decode circuitry 110 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device 130. An address page buffer 114 is in communication with I/O control circuitry 160 and row decode circuitry 108 and column decode circuitry 110 to latch the address signals prior to decoding. A command page buffer 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 110 to control the row decode circuitry 108 and column decode circuitry 110 in response to the addresses. In one embodiment, local media controller 135 includes the program convergence component 134, which can implement the corrective program convergence on memory device 130.

The local media controller 135 is also in communication with a cache page buffer 118. Cache page buffer 118 latches data, either incoming or outgoing, as directed by the local media controller 135 to temporarily store data while the array of memory cells 104 is busy writing or reading, respectively, other data. During a program operation (e.g., write operation), data may be passed from the cache page buffer 118 to the data page buffer 170 for transfer to the array of memory cells 104; then new data may be latched in the cache page buffer 118 from the I/O control circuitry 160. During a read operation, data may be passed from the cache page buffer 118 to the I/O control circuitry 160 for output to the memory sub-system controller 115; then new data may be passed from the data page buffer 170 to the cache page buffer 118. The cache page buffer 118 and/or the data page buffer 170 may form (e.g., may form a portion of) a page buffer of the memory device 130. A page buffer may further include sensing devices (not shown in FIG. 1B) to sense a data state of a memory cell of the array of memory cells 104, e.g., by sensing a state of a data line connected to that memory cell. A status page buffer 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 132 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 136 and outputs data to the memory sub-system controller 115 over I/O bus 136.

For example, the commands may be received over input/output (I/O) pins [7:0] of I/O bus 136 at I/O control circuitry 160 and may then be written into command page buffer 124. The addresses may be received over input/output (I/O) pins [7:0] of I/O bus 136 at I/O control circuitry 160 and may then be written into address page buffer 114. The data may be received over input/output (I/O) pins [7:0] for an 8-bit device or input/output (I/O) pins [15:0] for a 16-bit device at I/O control circuitry 160 and then may be written into cache page buffer 118. The data may be subsequently written into data page buffer 170 for programming the array of memory cells 104.

In an embodiment, cache page buffer 118 may be omitted, and the data may be written directly into data page buffer 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIGS. 1A-1B has been simplified. It should be recognized that the functionality of the various block components described with reference to FIGS. 1A-1B may not necessarily be segregated to distinct components or component portions of an integrated circuit device. For example, a single component or component portion of an integrated circuit device could be adapted to perform the functionality of more than one block component of FIGS. 1A-1B. Alternatively, one or more components or component portions of an integrated circuit device could be combined to perform the functionality of a single block component of FIGS. 1A-1B. Additionally, while specific I/O pins are described in accordance with popular conventions for receipt and output of the various signals, it is noted that other combinations or numbers of I/O pins (or other I/O node structures) may be used in the various embodiments.

FIGS. 2A-2B are diagrams of portions of an example array of memory cells included in a memory device, in accordance with some embodiments of the present disclosure. For example, FIG. 2A is a schematic of a portion of an array of memory cells 200A as could be used in a memory device (e.g., as a portion of array of memory cells 104). Memory array 200A includes access lines, such as wordlines 2020 to 202N, and a data line, such as bitline 204. The wordlines 202 may be connected to global access lines (e.g., global wordlines), not shown in FIG. 2A, in a many-to-one relationship. For some embodiments, memory array 200A may be formed over a semiconductor that, for example, may be conductively doped to have a conductivity type, such as a p-type conductivity, e.g., to form a p-well, or an n-type conductivity, e.g., to form an n-well.

Memory array 200A can be arranged in rows each corresponding to a respective wordline 202 and columns each corresponding to a respective bitline 204. Rows of memory cells 208 can be divided into one or more groups of physical pages of memory cells 208, and physical pages of memory cells 208 can include every other memory cell 208 commonly connected to a given wordline 202. For example, memory cells 208 commonly connected to wordline 202N and selectively connected to even bitlines 204 (e.g., bitlines 2040, 2042, 2044, etc.) may be one physical page of memory cells 208 (e.g., even memory cells) while memory cells 208 commonly connected to wordline 202N and selectively connected to odd bitlines 204 (e.g., bitlines 2041, 2043, 2045, etc.) may be another physical page of memory cells 208 (e.g., odd memory cells). Although bitlines 2043-2045 are not explicitly depicted in FIG. 2A, it is apparent from the figure that the bitlines 204 of the array of memory cells 200A may be numbered consecutively from bitline 2040 to bitline 204M. Other groupings of memory cells 208 commonly connected to a given wordline 202 may also define a physical page of memory cells 208. For certain memory devices, all memory cells commonly connected to a given wordline might be deemed a physical page of memory cells. The portion of a physical page of memory cells (which, in some embodiments, could still be the entire row) that is read during a single read operation or programmed during a single programming operation (e.g., an upper or lower page of memory cells) might be deemed a logical page of memory cells. A block of memory cells may include those memory cells that are configured to be erased together, such as all memory cells connected to wordlines 2020-202N (e.g., all strings 206 sharing common wordlines 202). Unless expressly distinguished, a reference to a page of memory cells herein refers to the memory cells of a logical page of memory cells.

Each column can include a string of series-connected memory cells (e.g., non-volatile memory cells), such as one of strings 2060 to 206M. Each string 206 can be connected (e.g., selectively connected) to a source line 216 (SRC) and can include memory cells 2080 to 208N. The memory cells 208 of each string 206 can be connected in series between a select gate 210, such as one of the select gates 2100 to 210M, and a select gate 212, such as one of the select gates 2120 to 212M. In some embodiments, the select gates 2100 to 210M are source-side select gates (SGS) and the select gates 2120 to 212M are drain-side select gates. Select gates 2100 to 210M can be connected to a select line 214 (e.g., source-side select line) and select gates 2120 to 212M can be connected to a select line 215 (e.g., drain-side select line). The select gates 210 and 212 might represent a plurality of select gates connected in series, with each select gate in series configured to receive a same or independent control signal. A source of each select gate 210 can be connected to SRC 216, and a drain of each select gate 210 can be connected to a memory cell 2080 of the corresponding string 206. Therefore, each select gate 210 can be configured to selectively connect a corresponding string 206 to SRC 216. A control gate of each select gate 210 can be connected to select line 214. The drain of each select gate 212 can be connected to the bitline 204 for the corresponding string 206. The source of each select gate 212 can be connected to a memory cell 208N of the corresponding string 206. Therefore, each select gate 212 might be configured to selectively connect a corresponding string 206 to the bitline 204. A control gate of each select gate 212 can be connected to select line 215.

In some embodiments, and as will be described in further detail below with reference to FIG. 2B, the memory array in FIG. 2A is a three-dimensional memory array, in which the strings 206 extend substantially perpendicular to a plane containing SRC 216 and to a plane containing a plurality of bitlines 204 that can be substantially parallel to the plane containing SRC 216.

FIG. 2B is another schematic of a portion of an array of memory cells 200B (e.g., a portion of the array of memory cells 104) arranged in a three-dimensional memory array structure. The three-dimensional memory array 200B may incorporate vertical structures which may include semiconductor pillars where a portion of a pillar may act as a channel region of the memory cells of strings 206. The strings 206 may be each selectively connected to a bit line 2040-204M by a select gate 212 and to the SRC 216 by a select gate 210. Multiple strings 206 can be selectively connected to the same bitline 204. Subsets of strings 206 can be connected to their respective bitlines 204 by biasing the select lines 2150-215L to selectively activate particular select gates 212 each between a string 206 and a bitline 204. The select gates 210 can be activated by biasing the select line 214. Each wordline 202 may be connected to multiple rows of memory cells of the memory array 200B. Rows of memory cells that are commonly connected to each other by a particular wordline 202 may collectively be referred to as tiers.

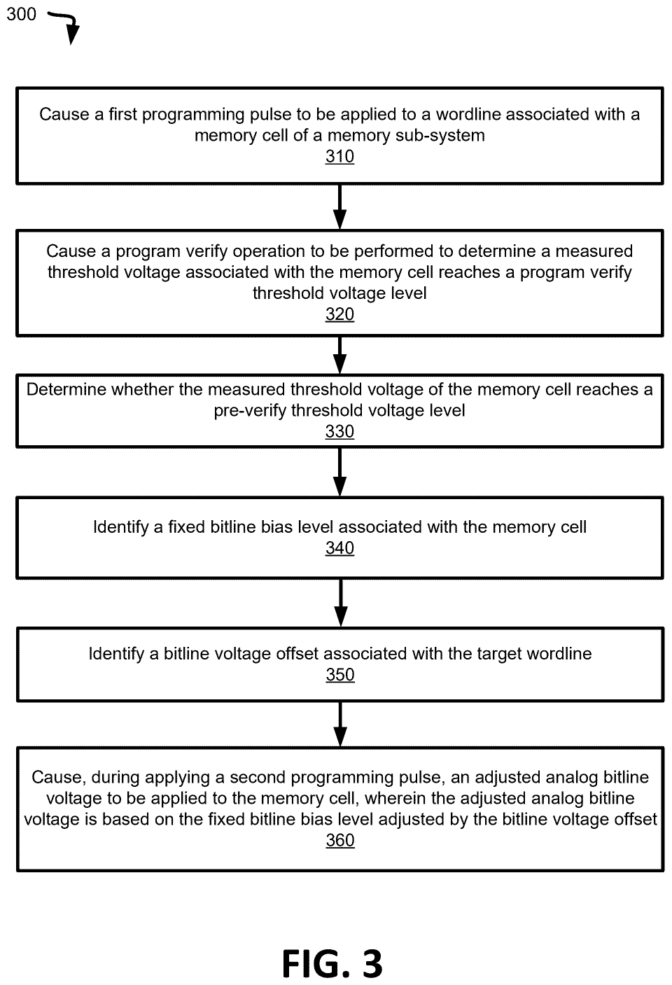

FIG. 3 is a flow diagram of an example method 300 to implement the corrective program convergence associated with memory cells of a memory sub-system, in accordance with some embodiments of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 300 is managed by the program convergence component 134 of FIG. 1A. In an embodiment the program convergence component 134 issues commands to cause one or more row drivers of the memory device 130 to apply a programming pulse. In an embodiment, the program convergence component 134 manages aspects of the method 300 using sense circuitry.

At operation 310, the processing device may cause a program operation to be initiated to program the set of target memory cells of the target wordline to a target programming level. In some implementations, the processing device can cause the program operation to be initiated to program the set of target memory cells of a target wordline (WLn) to a target programming level (e.g., L1, L2, L3 . . . or L15 of a QLC memory device). In some implementations, the processing device can receive, from a requestor, such as a memory interface 113 of a memory sub-system controller 115, a request to perform a memory access operation on a memory array, such as memory array 200A, of a memory device, such as memory device 130. In some implementations, the request includes a set of physical or logical addresses corresponding to the set of memory cells to be programmed. In some implementations, the processing device identifies the set of memory cells based on the set of addresses provided as part of the request. The request can be a program command received via a memory sub-system controller (e.g., the memory sub-system controller 115). In some implementations, the memory access operation comprises a program operation to program the set of memory cells to a set of programming levels (e.g., L1 to L7; wherein L0 is an erase state). In some implementations, the program operation is directed to one or more specific memory cell addresses. Each target memory cell of the set of target memory cells is connected to the target wordline.

In some implementations, the processing device can identify the set of memory cells (e.g., a subset of the memory cells of memory array 200A of FIG. 2A, such as those memory cells associated with a certain wordline or multiple wordlines of memory array) to be programmed. In some implementations, the set of memory cells are configured as any type of memory cells, such as MLC, TLC, or QLC memory cells (e.g., any type of memory cells that store more than one bit per cell including 2 bits, 3 bits, 4 bits, or more bits per cell). In some implementations, the identified set of memory cells are to be programmed to multiple programming levels (e.g., L1, L2. . . . L7 for a TLC memory device).

In some implementations, the program operation may include a series of operations, for example, including starting a program operation with some hardware initialization, performing a seed operation in which cells of the wordline are preconditioned to a particular voltage, causing a pulse to program the wordline, performing a wordline/bitline recovery of the sub-block, performing a program verify operation to check whether the sub-block has been programmed to a particular threshold program verify voltage, perform a final verification operation to determine whether the programming has completed, and ending the program operation. In some implementations, to program the memory cells, a series of pulses of voltage levels having an increasing magnitude (e.g., by a predefined pulse step height) are applied to wordlines to which one or more memory cells are connected to gradually raise the voltage level of the memory cells to above a wordline voltage level corresponding to the memory access operation (e.g., a target programming level).

For example, at operation 310, the processing device may cause a first programming pulse to be applied to a wordline associated with a memory cell of a memory sub-system. In some implementations, the processing device may issue a command to cause one or more row drivers associated with the memory cell to apply the programming pulse to the wordline. In some implementations, the processing device may apply the first programming pulse in response to receiving a programming operation request from a host system. In some implementations, the first programming pulse may be an initial pulse of a series of incrementing voltage programming pulses and have a first or initial voltage value that is based on a predetermined programming voltage associated with the host data.

In some implementations, if the memory sub-system controller performs an operating of migrating data from SLC cache to TLC memory device, the processing device may receive a read command that includes the data pattern for subsequent neighbor wordline (WLn+1) and determine the group for target wordline (WLn).

In some implementations, if the memory sub-system controller performs a write operation by allocating large SRAM, the processing device may need to distinguish the group for target wordline (WLn) based on neighbor wordline's data.

At operation 320, the processing device may perform a program verify operation to verify programming of the set of memory cells to a target programming level. For example, the processing device may initiate a program verify operation to determine whether a measured threshold voltage associated with the memory cell has reached a voltage value corresponding to a target programming level (i.e., program verify threshold voltage level (Vₚᵥ). In some implementations, the processing device may compare the measured threshold voltage with a program verify threshold voltage level. In some implementations, the program verify operation is performed by a combination of the processing device and sense circuitry associated with the memory cell of the memory sub-system, and the measured threshold voltage is stored by elements of the sense circuitry. In some implementations, the program verify operation involves applying a read voltage to the memory cell to obtain a measured threshold voltage and determining whether the measured threshold voltage of the memory cell is less than Vpv associated with the target programming level. In an embodiment, a sensing node associated with the memory cell stores the measured threshold voltage associated with the memory cell. In an embodiment, the sensing node can be a temporary storage location (e.g., a cache storage) of a sensing circuit associated with the memory cell.

At operation 330, the processing device may determine that a measured threshold voltage of the memory cell satisfies a threshold criterion. In some implementations, determining that the measured threshold voltage of the memory cell satisfies the threshold criterion further involves comparing the measured threshold voltage with a pre-verify threshold voltage level, where the threshold criterion is satisfied responsive to that the measured threshold voltage is larger than the pre-verify threshold voltage level and smaller than a program verify threshold voltage level.

In some implementations, at operation 330, responsive to determining that the measured threshold voltage of the memory cell does not reach the program verify threshold voltage level (Vₚᵥ), the processing device may determine whether the measured threshold voltage of the memory cell reaches a pre-verify threshold voltage level (V_{pre-verify}). In an embodiment, each programming level has a pre-verify threshold voltage level that is less than the program verify threshold voltage level (Vₚᵥ) of that programming level. In an embodiment, at operation 330, the processing device may determine whether the measured threshold voltage of the memory cell is greater than the pre-verify threshold voltage level (V_{pre-verify}) and less than the program verify threshold voltage level (Vₚᵥ). For example, the processing device identifies the measured threshold voltage stored in the sensing node and compare the measured threshold voltage of the memory cell with the pre-verify threshold voltage level (V_{pre-verify}) of the target programming level to make the determination.

At operation 340, the processing device may identify a fixed bitline bias level (Vsspc) associated with the memory cell. In some implementations, identifying the fixed bitline bias level associated with the memory cell is performed via a look-up operation of a stored or predetermined value. In some implementations, the fixed bitline bias level is a preset value that is typically greater than ground voltage level (i.e., 0V) and less than the inhibit voltage (e.g., V_{CC}).

At operation 350, the processing device may identify, based on programming level information of the immediately subsequent neighbor wordline, a bit voltage offset associated with the target memory cells. In some implementations, the bitline voltage offset is specific to the target programming level of the target memory cell(s). In some implementations, the programming level information of the immediately subsequent neighbor wordline comprises categorized programing levels of the immediately subsequent neighbor wordline (or aggressor memory cells) as described below. In some implementations, a magnitude of each respective bitline voltage offset depends on the number of bits of information reflecting a threshold voltage (i.e., programming level) of one or more aggressor memory cells. In some implementations, the bitline voltage offset is identified based on a data structure storing a plurality of bitline voltage offsets, each bitline voltage offset of the plurality of bitline voltage offsets corresponding to a programming level of the memory cell and a categorized programming level of the first wordline.

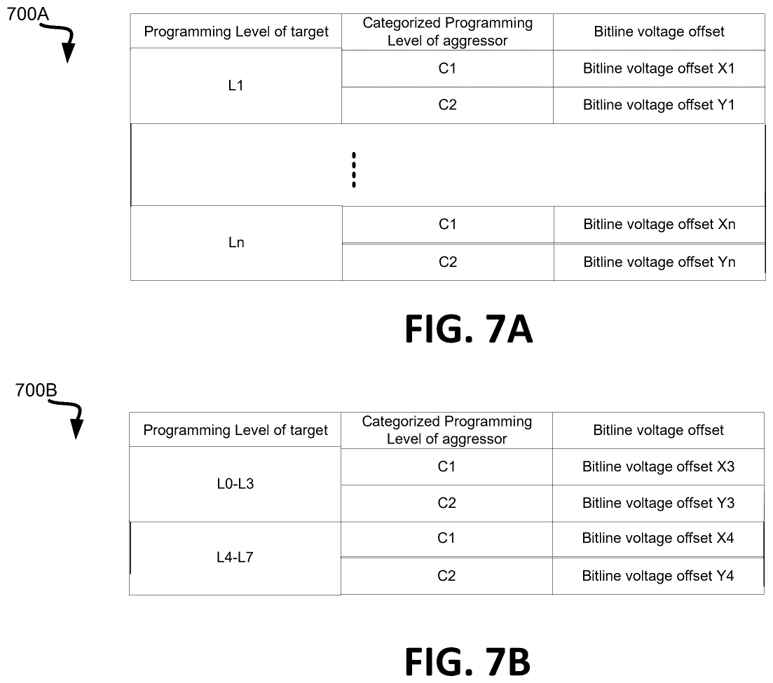

In some implementations, the bitline voltage offset may be specifically determined such that the bitline voltage applied to the target memory cells can compensate for cell-to-cell (C2C) coupling with achieving a desired RWB increase. In some implementations, the bitline voltage may be adjusted by an offset voltage amount (herein referred to as the “bitline voltage offset”). The bitline voltage offset may be determined based on the programming level of immediately subsequent neighbor wordline (WLn+1). In some implementations, the bitline voltage offset is specific to the target programming level of the target memory cells. In some implementations, the processing device may identify the bitline voltage offset by performing a look-up operation of a data structure storing the preset bitline voltage offset. In an embodiment, the bitline voltage offset may be determined via a look-up of a stored or predetermined value corresponding to a programming level of the target memory cells and a categorized programming level of the immediately subsequent neighbor wordline (WLn+1). FIGS. 7A and 7B illustrate examples of data structures that store bitline voltage offsets.

As shown in the example data structure 700A in FIG. 7A, the target memory cell may be a specific type of cell (e.g., MLC, TLC, QLC, etc.), which can be programmed to programming levels L1-Ln. For each programming level L1-Ln, a respective bitline voltage offset is determined based on the categorized programming level of aggressor memory cell. For example, in a situation where programming level information of 1-bit aggressor memory cell is used, the programming levels of the aggressor memory cell can be categorized as high or low programming level (e.g., C1, C2) since those two categorizations can be represented with a single binary bit. In this example, when the target programming level of the target memory cell is L1, the program component can determine that the effects of the aggressor memory cell programmed to the low programming level C1 may need to use a bitline voltage offset X1 less than a default bitline voltage, and the program component can determine that the bitline voltage used to compensate for the effect of the target memory cells caused by the aggressor memory cells programmed to the high programming level C2 may need a bitline voltage offset Y1 less than a default bitline voltage used regardless of the programming level to which the target memory cell is being programmed. Similarly, for programming level Ln of the target memory cell, when the aggressor memory cell is to be programmed to the low programming level C1, bitline voltage offset Xn is used, and when the aggressor memory cell is to be programmed to the high programming level C2, bitline voltage offset Yn is used; and so on. As such, for each programming level of the target memory cell, for each categorized programming level (e.g., based on the 1-bit programming level (e.g., low programming level C1 or high programming level C2)) of the aggressor memory cell, a respective bitline voltage offset is used.

For example, programming levels of the aggressor memory cell is categorized into two categorization, where the first category is a programming level below L5 and the second category is a programming level above or equal to L5. When the aggressor memory cell is to be programmed to the programming level in the first category (i.e., less than L5), the bitline voltage offset X1 may be 0 for programming level L1 of the target memory cells, and when the aggressor memory cell is to be programmed to the programming level in the second category (i.e., not less than L5), the bitline voltage offset Y1 may be a positive value for programming level L1 of the target memory cells.

Although the programming level information of 1-bit aggressor memory cell is used in the illustration of FIG. 7A for two categorizations, other number of categorizations of programming level of the aggressor memory cell can be used. For example, for each programming level of the target memory cell, in a situation where programming level information of 2-bit aggressor memory cell is used, the programming levels of the aggressor memory cell can be categorized to either be four categorized programming level (e.g., C1, C2, C3, C4), for each categorized programming level of the aggressor memory cell, a respective bitline voltage offset can be used.

In an embodiment, instead of providing respective bitline voltage offset to each programming level of the target memory cell, certain programming levels of the target memory cell can be grouped such that they can use the same bitline voltage offsets, which is illustrated with respect to FIG. 7B. In one example, the program component can initially group the programming levels of the target memory cell into one group, which means that regardless of the programming level to which the target memory cell is being programmed, the same bitline voltage offsets are used. In some implementations, having grouped the programming levels into one group, the program component can cycle through a pre-determined set of potential bitline voltage offset values until the value that maximizes the RWB increase (e.g . . . , including reduced Vt distribution width) is found. Further, the value that results in the greatest RWB increase for the grouping can be compared to the maximum RWB increase (i.e., the RWB increase resulting from perfect compensation e.g., as calculated by using the Law of Total Variance, to determine the reduction of the spread of the Vt distribution for a particular programming level) to determine whether the target RWB increase is achieved. If the greatest RWB increase that can be obtained using the chosen grouping of the specified cell programming levels is not equal to or greater than the target RWB increase, the program component can divide the programming levels into more groups.

In the example shown in FIG. 7B, the program component can group the programming levels of the target memory cell into two groups. For example, programming levels L0-L3 can be grouped as a first group and programming levels L4-L7 can be grouped as a second group. For example, in a situation where programming level information of 1-bit aggressor memory cell is used, for each programming level in the first group (i.e., L0-L3), when the aggressor memory cell is to be programmed to the low programming level C1, bitline voltage offset X3 is used, and when the aggressor memory cell is to be programmed to the high programming level C2, bitline voltage offset Y3 is used. For each programming level in the second group (i.e., L4-L7), when the aggressor memory cell is to be programmed to the low programming level C1, bitline voltage offset X4 is used, and when the aggressor memory cell is to be programmed to the high programming level C2, bitline voltage offset Y4 is used.

Referring back to FIG. 3, at operation 360, the processing device may cause an adjusted analog bitline voltage to be applied to the bitline connected to the target memory cells during a second programing pulse applied to the target memory cells, where the adjusted analog bitline voltage (e.g., adjusted analog bitline voltage 560) is a continuous voltage value that starts from ground voltage level to an adjusted bitline voltage level, where the adjusted bitline voltage level is the bitline voltage level (identified in operation 340) reduced by the bitline voltage offset (identified in operation 350).

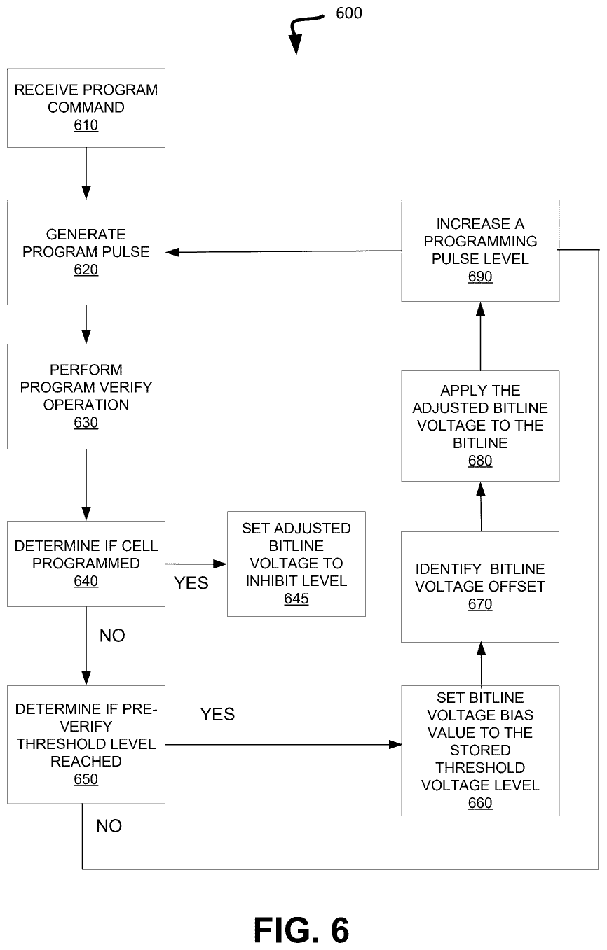

In some implementations, the processing device may continue the execution of method 300 recursively until it is determined that the target programming level of the memory cell is verified in operation 320. An example flow method 600 for the recursive execution is illustrated with respect to FIG. 6.

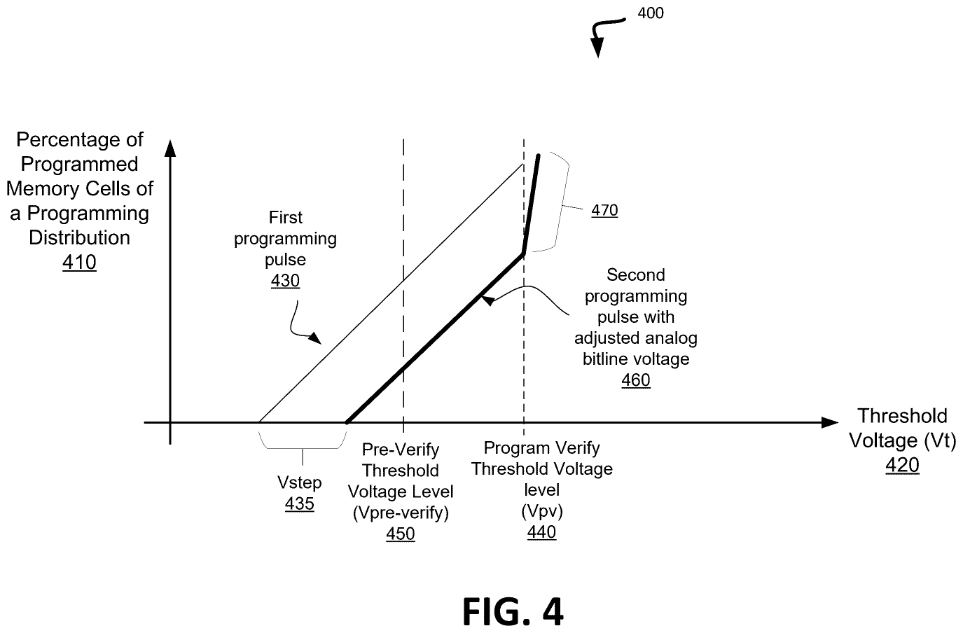

FIG. 4 illustrates an example graph 400 including a representation of the corrective programming convergence associated with memory cells using an adjusted analog bitline voltage, according to embodiments. As shown, the graph 400 includes a plot of a percentage of programmed memory cells of a programming distribution 410 with respect to a measured threshold voltage 420. In an embodiment, the memory cells are subjected to a series of programming pulses, including a first programming pulse 430 and a second programming pulse 440, to program the respective memory cells to a target programming state. The second programming pulse 460 are incremented by a step voltage (Vstep) 435 from the first programming pulse 430. The first programming pulse 430 is applied along with a normal bitline voltage, where the second programming pulse 460 is applied along with an adjusted analog bitline voltage (e.g., as illustrated in operation 360).

Specifically, after a first programming pulse 430 is applied to the target memory cells, a program verify operation is performed to measure the threshold voltages of the memory cells and compare the measured threshold voltages with a program verify threshold voltage level (Vₚᵥ) 440. As illustrated, the measured threshold voltage of the memory cell measured following the first programming pulse 430 are less than the program verify threshold voltage level (Vₚᵥ) 440, and, as such, the memory cells has not be programmed to a target programming level after applying the first programming pulse 430. The program convergence component 134 may then compare the measured threshold voltage of the memory cell with a pre-verify threshold voltage level (V_{pre-verify}) 450. As shown, the pre-verify threshold voltage level (V_{pre-verify}) 450 is less than the program verify voltage level (Vₚᵥ) 440 and can be used to identify memory cells that are approaching a programming level for which the slowing of programming speed is desired. In an embodiment, upon determining that the one or more memory cells having a measured threshold voltage that is between the pre-verify threshold voltage level (V_{pre-verify}) 450 and the program verify voltage level (Vₚᵥ) 440, an adjusted analog bitline voltage is applied to the respective bitlines during a second programming pulse 460. As shown, during the second programming pulse 460 with the adjusted analog bitline voltage, programming speed of the memory cell is slowed as indicated by the line portion 470.

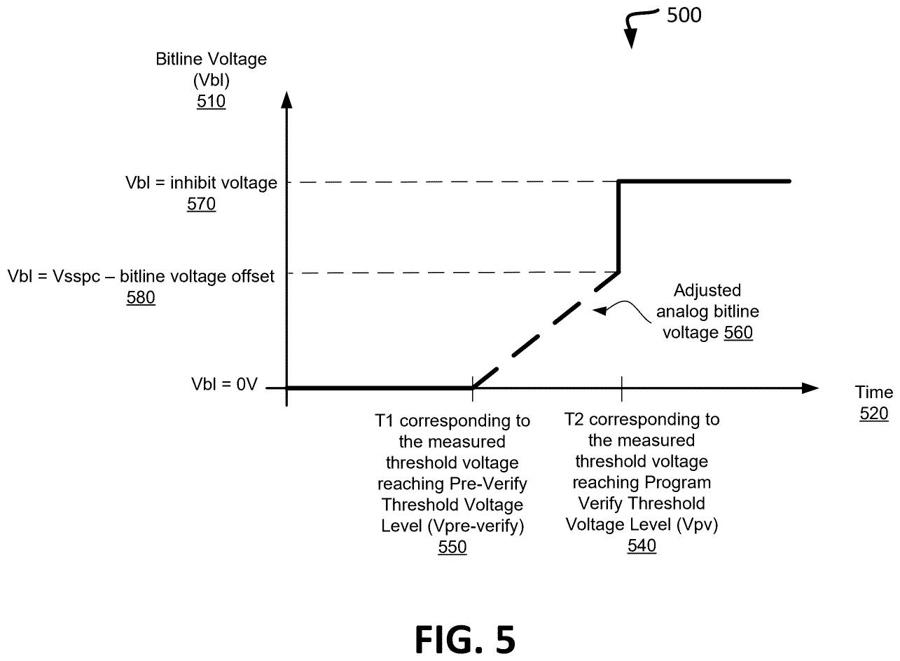

FIG. 5 illustrates an example graph 500 including a representation of applying a bitline voltage (V_{bl}) 510 to the memory cells to implement corrective program convergence associated with the memory cells according to embodiments. As shown, the graph 500 includes a plot of the bitline voltage 510 applied during a series of programming pulses with respect to time 520. As shown in FIGS. 4 and 5, the memory cells are subjected to the series of programming pulses (e.g., the first programming pulse 430 and the second programming pulse 460) to program the respective memory cells to a particular programming state, during the first programming pulse, the bitline voltage is set to 0V (e.g., no biasing of the bitline is performed). As illustrated in FIGS. 4 and 5, during the second programming pulse, an adjusted continuous or analog bitline voltage 560 is applied to the memory cells. The adjusted continuous or analog bitline voltage 560 is a gradually increased voltage starting from 0V, at the time T1, until reaching an adjusted bitline bias level 580 at the time T2, where adjusted bitline bias level 580 is a fixed bitline bias level (Vsspc) (e.g., identified at operation 340) reduced by the bitline voltage offset (e.g., identified at operation 350). T1 is the time when the measured threshold voltage reaches pre-verify threshold voltage level (V_{pre-verify}) 450, and T2 is the time when the measured threshold voltage reaches program verify voltage level (Vₚᵥ) 440.

FIG. 6 is a flow diagram of an example method 600 to implement corrective program convergence associated with memory cells of a memory sub-system, in accordance with some embodiments of the present disclosure. The method 600 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 600 is performed by the program convergence component 134 of FIG. 1A.

At operation 610, a program command is received. For example, the processing device receives a command, such as a command to program data to one or more memory cells. In some implementations, if the memory sub-system controller performs an operating of migrating data from SLC cache to TLC memory device, the processing device may receive a read command that includes the data pattern for subsequent neighbor wordline (WLn+1) and determine the group for target wordline (WLn). In some implementations, if the memory sub-system controller performs a write operation by allocating large SRAM, the processing device may need to distinguish the group for target wordline (WLn) based on neighbor wordline's data

In response to the command, at operation 620, a program pulse is generated, which may be same as or similar to operation 310. For example, the processing device causes a programming pulse (e.g., the first programming pulse 430 of FIG. 4) to be generated and applied to the selected wordline. In an embodiment, during the programming pulse applied in operation 620, no bias voltage is applied to the bitline associated with the selected wordline.

At operation 630, a program verify operation is performed, which may be same as or similar to operation 320. For example, the processing device performs a program verify operation to determine if the memory cell has been properly programmed. In one embodiment, the processing device reads the voltage level stored in the memory cell and compares read voltage level (i.e., measured threshold voltage) to a target programming level to confirm whether the voltage level has reached the target programming level. For example, the processing device can store the measured threshold voltage identified during the program verify operation 630 in a storage location (e.g., a sensing node) associated with the memory cell.

At operation 640, a determination is made, which may be same as or similar to operation 320. For example, the processing device can determine whether the cell was properly programmed. In one embodiment, if the voltage level read during the program verify operation has reached the target programming level, the processing device determines that the memory cell was properly programmed. If, at operation 640, the memory cell has been programmed, at operation 645, the bitline voltage is increased to a program inhibit voltage level. In one embodiment, the bitline voltage is increased from OV to an inhibit voltage (e.g., V_{CC}).

If, at operation 640, the processing device determines that the memory cell is not yet programmed with the target programming level, at operation 650, a determination is made, which may be same as or similar to operation 330. For example, the processing device can check the measured threshold voltage for the memory cell to determine if it has reached a pre-verify threshold voltage level. In an embodiment, each programming level has a pre-verify threshold voltage level, and when the measured threshold voltage reaches pre-verify threshold voltage level, the programming of that particular memory cell is slowed down by biasing the voltage of bitline coupled to the memory cell. As shown in FIG. 6, if the processing device determines that the measured threshold level is below the pre-verify threshold voltage level, the processing device increases a programming pulse level (e.g., by the Vstep value of FIG. 4) at operation 690 and returns to operation 620 to generate a subsequent programming pulse.

In an embodiment, if the processing device determines that the measured threshold level has reached the pre-verify threshold voltage level at operation 650, the method 600 proceeds to operation 660. At operation 660, a bitline voltage bias level is set, which may be same as or similar to operation 340. For example, the processing device identifies the threshold voltage stored at the sensing node in operation 630, and sets the fixed bitline voltage bias level of the stored threshold voltage.

At operation 670, a bitline voltage offset is identified, which may be same as or similar to operation 350. At operation 680, an adjusted analog bitline voltage is applied, which may be same as or similar to operation 360. For example, the processing device causes the adjusted analog bitline voltage to be applied to the bitline of the selected memory cell during a subsequent programming pulse, where the subsequent programming pulse is increased at operation 690.

Advantageously, the processing device selectively slows the programming of each memory cell that has passed the pre-verify threshold for the target programming level by applying an adjusted continuous bitline voltage. In an embodiment, other memory cells (e.g., the memory cells having a measured threshold voltage that is not between the pre-verify threshold voltage level and the program verify threshold voltage level) being programmed are unaffected by the bitline biasing and are allowed to be programmed at their normal programming speed, thereby producing the beneficial effect of efficiently narrowing the threshold voltage distribution without reducing the programming throughput.

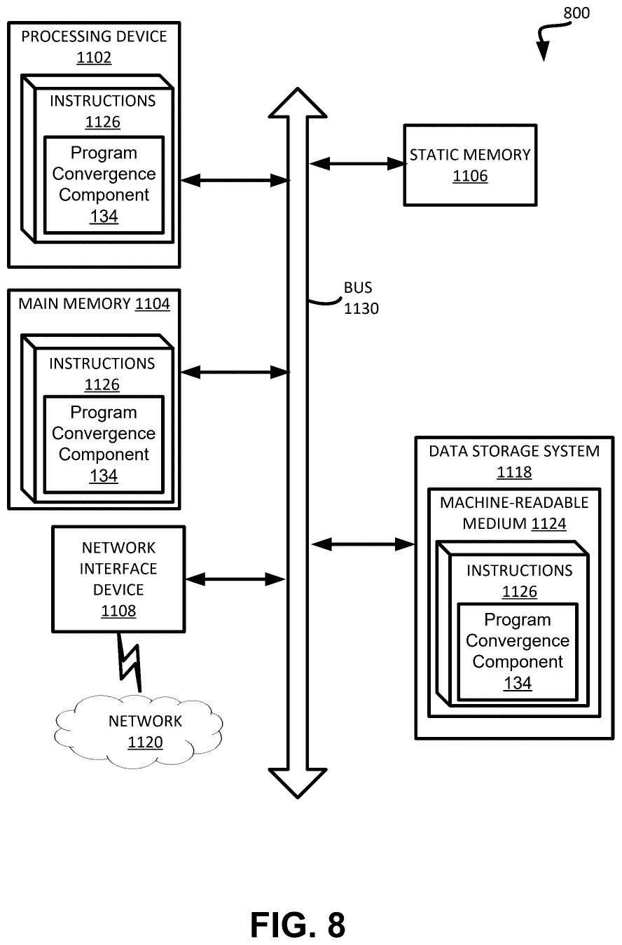

FIG. 8 illustrates an example machine of a computer system 800 within which a set of instructions, for causing the machine to perform any one or more of the methodologies discussed herein, can be executed. In some embodiments, the computer system 800 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the program convergence component 134 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 800 includes a processing device 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a data storage system 818, which communicate with each other via a bus 830.

Processing device 802 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 802 can also be one or more special-purpose processing devices such as an application specific integrated circuit (ASIC), a field programmable gate array (FPGA), a digital signal processor (DSP), network processor, or the like. The processing device 802 is configured to execute instructions 826 for performing the operations and steps discussed herein. The computer system 800 can further include a network interface device 808 to communicate over the network 820.

The data storage system 818 can include a machine-readable storage medium 824 (also known as a computer-readable medium) on which is stored one or more sets of instructions 826 or software embodying any one or more of the methodologies or functions described herein. The instructions 826 can also reside, completely or at least partially, within the main memory 804 and/or within the processing device 802 during execution thereof by the computer system 800, the main memory 804 and the processing device 802 also constituting machine-readable storage media. The machine-readable storage medium 824, data storage system 818, and/or main memory 804 can correspond to the memory sub-system 110 of FIG. 1.

In one embodiment, the instructions 826 include instructions to implement functionality corresponding to a selective relocation component (e.g., the program convergence component 134 of FIG. 1). While the machine-readable storage medium 824 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array comprising:
a memory cell connected to a target wordline; and
a first wordline adjacent to the target wordline, wherein the first wordline is to be programmed immediately subsequent to the target wordline; and
control logic, operatively coupled with the memory array, to perform operations comprising:
causing a first programming pulse to be applied to the target wordline associated with the memory cell;
causing a program verify operation to be performed on the memory cell to verify programming of the memory cell to a target programming level;
determining that a measured threshold voltage of the memory cell satisfies a threshold criterion;
identifying a fixed bitline bias level associated with the memory cell;
identifying, based on programming level information of the first wordline, a bitline voltage offset associated with the memory cell; and
causing, during applying a second programming pulse, an adjusted analog bitline voltage to be applied to the memory cell, wherein the adjusted analog bitline voltage is based on the fixed bitline bias level adjusted by the bitline voltage offset.

2. The memory device of claim 1, wherein the bitline voltage offset is specific to the target programming level.

3. The memory device of claim 1, wherein the programming level information of the first wordline depends on a number of bits of information reflecting a threshold voltage of one or more aggressor memory cells of the first wordline.

4. The memory device of claim 1, wherein the bitline voltage offset is identified based on a data structure storing a plurality of bitline voltage offsets, each bitline voltage offset of the plurality of bitline voltage offsets corresponding to a programming level of the memory cell and a categorized programming level of the first wordline.

5. The memory device of claim 1, wherein causing the program verify operation to be performed on the memory cell to verify programming of the memory cell to the target programming level further comprises:
comparing the measured threshold voltage with a program verify threshold voltage level.

6. The memory device of claim 1, wherein determining that the measured threshold voltage of the memory cell satisfies the threshold criterion further comprises:
comparing the measured threshold voltage with a pre-verify threshold voltage level, wherein the threshold criterion is satisfied responsive to that the measured threshold voltage is larger than the pre-verify threshold voltage level and smaller than a program verify threshold voltage level.

7. The memory device of claim 1, wherein identifying the fixed bitline bias level associated with the memory cell is performed via a look-up operation of a stored or predetermined value.

8. The memory device of claim 1, wherein the adjusted analog bitline voltage is a continues voltage starting from a ground voltage level until reaching a level that is the fixed bitline bias level reduced by the bitline voltage offset.

9. A method comprising:
causing, by a processing device coupled with a memory array, a first programming pulse to be applied to a target wordline associated with a memory cell, wherein the memory array comprises the memory cell connected to the target wordline and a first wordline adjacent to the target wordline, and wherein the first wordline is to be programmed immediately subsequent to the target wordline;
causing a program verify operation to be performed on the memory cell to verify programming of the memory cell to a target programming level;
determining that a measured threshold voltage of the memory cell satisfies a threshold criterion;
identifying a fixed bitline bias level associated with the memory cell;
identifying, based on programming level information of the first wordline, a bitline voltage offset associated with the memory cell; and
causing, during applying a second programming pulse, an adjusted analog bitline voltage to be applied to the memory cell, wherein the adjusted analog bitline voltage is based on the fixed bitline bias level adjusted by the bitline voltage offset.

10. The method of claim 9, wherein the bitline voltage offset is specific to the target programming level.

11. The method of claim 9, wherein the programming level information of the first wordline depends on a number of bits of information reflecting a threshold voltage of one or more aggressor memory cells of the first wordline.

12. The method of claim 9, wherein the bitline voltage offset is identified based on a data structure storing a plurality of bitline voltage offsets, each bitline voltage offset of the plurality of bitline voltage offsets corresponding to a programming level of the memory cell and a categorized programming level of the first wordline.

13. The method of claim 9, wherein causing the program verify operation to be performed on the memory cell to verify programming of the memory cell to the target programming level further comprises:
comparing the measured threshold voltage with a program verify threshold voltage level.

14. The method of claim 9, wherein determining that the measured threshold voltage of the memory cell satisfies the threshold criterion further comprises:
comparing the measured threshold voltage with a pre-verify threshold voltage level, wherein the threshold criterion is satisfied responsive to that the measured threshold voltage is larger than the pre-verify threshold voltage level and smaller than a program verify threshold voltage level.

15. The method of claim 9, wherein identifying the fixed bitline bias level associated with the memory cell is performed via a look-up operation of a stored or predetermined value.

16. The method of claim 9, wherein the adjusted analog bitline voltage is a continues voltage starting from a ground voltage level until reaching a level that is the fixed bitline bias level reduced by the bitline voltage offset.

17. A non-transitory computer readable medium comprising instructions, which when executed by a processing device coupled with a memory array, cause the processing device to perform operations comprising:
causing a first programming pulse to be applied to a target wordline associated with a memory cell, wherein the memory array comprises the memory cell connected to the target wordline and a first wordline adjacent to the target wordline, and wherein the first wordline is to be programmed immediately subsequent to the target wordline;
causing a program verify operation to be performed on the memory cell to verify programming of the memory cell to a target programming level;
determining that a measured threshold voltage of the memory cell satisfies a threshold criterion;
identifying a fixed bitline bias level associated with the memory cell;
identifying, based on programming level information of the first wordline, a bitline voltage offset associated with the memory cell; and
causing, during applying a second programming pulse, an adjusted analog bitline voltage to be applied to the memory cell, wherein the adjusted analog bitline voltage is based on the fixed bitline bias level adjusted by the bitline voltage offset.

18. The non-transitory computer readable medium of claim 17, wherein the bitline voltage offset is specific to the target programming level.

19. The non-transitory computer readable medium of claim 17, wherein the programming level information of the first wordline depends on a number of bits of information reflecting a threshold voltage of one or more aggressor memory cells of the first wordline.

20. The non-transitory computer readable medium of claim 17, wherein the bitline voltage offset is identified based on a data structure storing a plurality of bitline voltage offsets, each bitline voltage offset of the plurality of bitline voltage offsets corresponding to a programming level of the memory cell and a categorized programming level of the first wordline.
